(19) United States
(12) Patent Application Publication
(10) Pub. No.: US 2014/0227498 A1
(43) Pub. Date: Aug. 14, 2014

(54) METHOD, SYSTEM FOR MANUFACTURING A CIRCUIT BOARD, AND THE CIRCUIT BOARD THEREOF

(71) Applicant: 3M INNOVATIVE PROPERTIES COMPANY, St. Paul, MN (US)

(72) Inventors: Hyung-Jin Song, Seoul (KR); Kyung-Ho Jang, Seoul (KR); Justina S. Lee, Singapore (SG)

(73) Assignee: 3M INNOVATIVE PROPERTIES COMPANY, St. Paul, MN (US)

(21) Appl. No.: 14/345,838

(22) PCT Filed: Sep. 12, 2012
(86) PCT No.: PCT/US2012/054891

§ 371 Date: Mar. 19, 2014

Related U.S. Application Data
(60) Provisional application No. 61/536,864, filed on Sep. 20, 2011.

(51) Int. Cl. H05K 3/00; H05K 1/05; B32B 7/02

(52) U.S. Cl. CPC H05K 3/0058; B32B 7/02; H05K 1/05
USPC 428/213; 156/60; 156/273.9; 156/379.7; 428/212

(57) ABSTRACT

The present invention provides a method and a system for manufacturing a circuit board for use during fabrication of LEDs. The method includes individual processes (in no particular order) like continuous contacting of various layers of the circuit board, B-staging of an adhesive used in the circuit board, pre-heating of the various layers when the various layers are arranged in an adjacent manner to each other, applying pressure to the circuit board when the various layers are arranged in an adjacent manner to each other, thermal curing of the adhesive and singulating the circuit board.

### TECHNICAL FIELD

The present invention relates to a method and a system for manufacturing a circuit board.

### BACKGROUND

Light emitting diodes (LEDs) are being used increasingly due to their illumination properties and low power consumption. In many instances, LEDs have been used to in place of incandescent fluorescent lamps.

Epoxy-based boards have been used for the manufacture of LEDs. However, metal-based boards are better suited for LEDs given the high temperatures generated during use of the LEDs. The high temperatures generated by LEDs may lead to degradation and warping of epoxy-based boards after an extended period of time. This may have an adverse effect on the longevity or reliability of the epoxy board mounted LEDs.

Another advantage of metal-based boards is as a heat sink to aid in removing heat generated during use of the LEDs. However, the use of metal-based boards may increase a cost of manufacturing LEDs, as typical processes for manufacturing metal-based boards utilize batch processes, which usually generate more wasted materials due to constraints in optimizing yield for each batch.

In this regard, given that metal-based boards are preferable for the manufacture of LEDs, it would be desirable if a yield (in relation to production time and optimizing use of materials used to manufacture the LEDs) when manufacturing LEDs with metal-based boards is optimized such that the cost for manufacturing LEDs with metal-based boards is lowered.

### SUMMARY

In a first aspect, there is provided a method for manufacturing a circuit board 10 (20). The method (20) includes continuously contacting a first layer 12 of a first impermeable material to a second layer 14 (22) of bonding material at a pre-determined rate of motion; B-staging the second layer 14 (24); continuously contacting a third layer 16 of a second impermeable material (28) to the second layer 14 at the pre-determined rate of motion; and thermal curing the B-staged second layer 14 (32). The pre-determined rate of motion may be between 2 to 60 m/min.

The method (20) may further include pre-heating of the first layer 12 (26) with the B-staged second layer 14 and the third layer 16; and applying pressure to the first layer 12 (30) with the B-staged second layer 14 and the third layer 16. The method may also further include singulating each circuit board (34) after thermal curing to prevent both shattering and partial uncuring of the second layer 14, the singulating being carried out before the second layer 14 cools to 100° C.

The bonding material may preferably comprise a polymerizable polymer and a curable epoxy, whereby both the polymerization of the polymer and the curing of the epoxy are by cross-linking. The first impermeable material may be provided from a continuous aluminum sheet while the second impermeable material may be provided from a continuous copper sheet. The aluminum sheet is preferably thicker than the copper sheet.

It is preferable that the B-staging of the second layer 14 (24) minimizes air pockets between the third layer 16 and the bonding material. The air pockets result from air bubbles formed in the bonding material and a viscosity of the bonding material increases after B-staging, the increase in the viscosity preferably allowing for film formation in the second layer 14. The B-staging (24) may be carried out for a duration of between 1 second to 300 seconds. Preferably, the duration is more than 5 seconds.

The B-staging (24) is preferably carried out using radiation such as, for example, UV, x-ray, visible light, infra-red and so forth. The UV radiation may be emitted at an intensity of 100 to 10000 mJ/cm². Preferably, the UV radiation is emitted at an intensity of 500 to 2000 mJ/cm². Alternatively, the B-staging (24) is carried out using heat emitted at a temperature of 50° C. to 250° C. Activating the B-staged second layer 14 may also include partial melting of the curable epoxy adjacent to an exposed surface of the second layer for increased adhesion to the third layer 16.

It is preferable that the pre-heating (26) activates the B-staged second layer 14 before contacting the third layer 16. Furthermore, the pre-heating (26) advantageously reduces a quantity of volatiles and dissolved gases in the second layer 14. The pre-heating (26) may be carried out at a temperature between 20° C. to 240° C. The pre-heating temperature is preferably between 70° C. to 200° C. Furthermore, the pre-heating (26) is carried out for a duration of between 1 second to 300 seconds, and preferably between 30 seconds to 200 seconds.

Preferably, the application of pressure (30) is for ensuring bonding of both the first layer 12 and the third layer 16 with the second layer 14. The applied pressure (30) may be between 1 to 100 kgf, and preferably between 10 to 50 kgf.

The thermal curing of the B-staged second layer 14 (32) may be for curing the epoxy, whereby the thermal curing (32) is carried out at a temperature between 100° C. to 300° C., and preferably, above 160° C. In addition, the thermal curing (32) may be carried out for a duration of between 1 minute to 5 minutes, and preferably, between 2 minutes to 4 minutes.

In a second aspect, there is also provided a system for manufacturing a circuit board 10 (60). The system (60) includes a coating mechanism (62) for continuously contacting a first layer 12 of a first impermeable material to a second layer 14 of bonding material at a pre-determined rate of motion; at least one coil winding mechanism (64) for continuously contacting a third layer 16 of a second impermeable material to the second layer 14; a UV source (66) for carrying out B-staging the second layer 14; a first heating enclosure (68) for carrying out pre-heating of the first layer 12 with the B-staged second layer 14 and the third layer 16; a laminator (70) for applying pressure to the first layer 12 with the B-staged second layer 14 and the third layer 16; and a second heating enclosure (72) for carrying out thermal curing of the B-staged second layer 14. The pre-determined rate of motion may be between 2 to 60 m/min.

The coating mechanism may be a slot-and-knife coater. The bonding material may preferably comprise a cross-linkable polymer and a curable epoxy. The first impermeable material may be a continuous aluminum sheet and the second impermeable material may be a continuous copper sheet. The aluminum sheet is preferably thicker than the copper sheet.

The B-staging of the second layer 14 advantageously minimizes air pockets between the third layer 16 and the bonding material. The air pockets result from air bubbles formed in the bonding material and a viscosity of the bonding material increases after B-staging, the increase in the viscosity advantageously allowing for film formation in the second layer 14.

The B-staging may be carried out for a duration of between 1 second to 300 seconds, preferably more than 5 seconds. In addition, the UV radiation from the UV source may be emitted at an intensity of 100-10000 mJ/cm², preferably at an intensity of 500 to 2000 mJ/cm².

The thermal curing of the B-staged second layer 14 is preferably for curing the epoxy, the thermal curing being carried out at a temperature between 20° C. to 240° C., and preferably above 160° C. The thermal curing may be carried out for a duration of between 1 minute to 5 minutes, and preferably between 2 minutes to 4 minutes.

The system (60) may further include a singulating mechanism (74) for singulating each circuit board 10 after thermal curing to prevent both shattering and partial uncuring of the second layer 14, the singulating preferably being carried out before the second layer 14 cools to 100° C.

In a final aspect, there is provided a circuit board 10. The circuit board 10 includes a first layer 12 of a first impermeable material, the first layer 12 being cut from a continuous sheet; a second layer 14 of a bonding material on the first layer 12; and a third layer of a second impermeable material on the second layer 14. Preferably, the first layer 12 and the third layer 16 are each bonded with the second layer 14, with the first layer 12 and the third layer 16 each having an in-plane dimension that is at least ten times greater than a thickness of the second layer 14.

The in-plane dimension of the first layer 12 and the third layer 16 each may preferably be either a hundred or a thousand times greater than the thickness of the second layer 14. Preferably, the first impermeable material is aluminum and the second impermeable material is copper.

It is advantageous that pre-heating of the second layer 14 reduces a quantity of volatiles and dissolved gases in the second layer 14. It is also advantageous that the at least ten times greater thickness of the first layer 12 and the third layer 16 in relation to the thickness of the second layer 14 increases an elastic modulus of the circuit board 10 to a value greater than 1000.

### BRIEF DESCRIPTION OF THE DRAWINGS

In order to ensure that the invention may be fully understood and readily put into practical effect, there is provided, by way of non-limitative example-only exemplary embodiments, the following illustrative figures which are referenced by the subsequent description:

FIG. 1 shows a cross-sectional view of a preferred embodiment of a circuit board of the present invention;

FIG. 2 shows a schematic view of a system of the present invention; and

FIG. 3 shows a process flow of a method of the present invention.

### DETAILED DESCRIPTION

The present invention provides a method and a system for manufacturing a circuit board for use during fabrication of LEDs. The method includes individual processes (in no particular order) like continuous contacting of various layers of the circuit board, B-staging of an adhesive used in the circuit board, pre-heating of the various layers when the various layers are arranged in an adjacent manner to each other, applying pressure to the circuit board when the various layers are arranged in an adjacent manner to each other, thermal curing of the adhesive and singulating the circuit board.

Correspondingly, the system includes constituents like, at least one coating mechanism, at least one coiling mechanism, a UV source, at least one heating enclosure and a laminator to carry out the various processes of the method as briefly described above. Furthermore, a circuit board with advantageous durability properties which results from use of the method or system is also provided in the present invention.

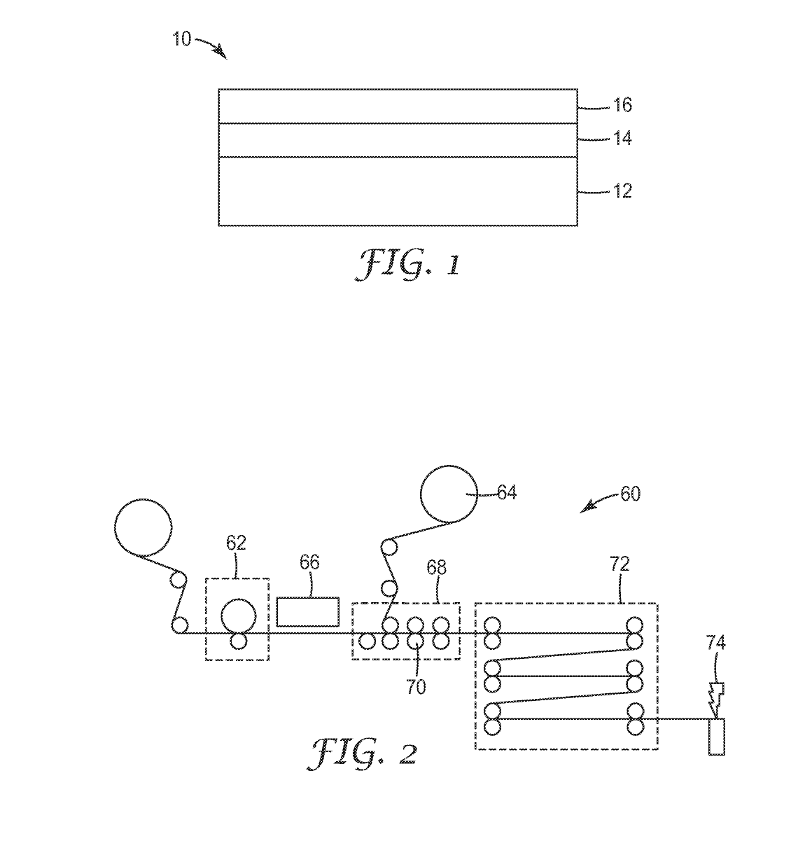

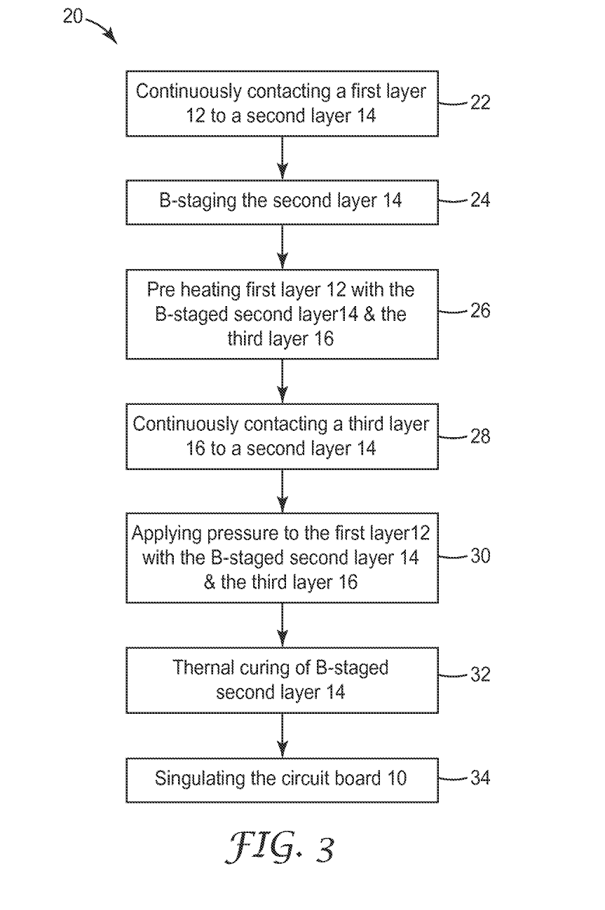

With reference to all Figures of the present application, there is shown a method (20) for manufacturing a circuit board 10. A system (60) for manufacturing the circuit board 10 will also be described when describing the method (20). The circuit board 10 may be usable for the fabrication of LEDs, and is able to dissipate heat. As shown in FIG. 1, the circuit board 10 is in a form of a multi-layer configuration, whereby various layers are adjacent to each other.

The method (20) includes continuously contacting a first layer 12 of a first impermeable material to a second layer 14 (22) of bonding material at a pre-determined rate of motion. The first impermeable material may be in a form of a continuous aluminum sheet, the first layer 12 being a metal base for the circuit board 10. The bonding material comprises a polymerizable polymer and a curable epoxy, whereby both the polymerization of the polymer and the curing of the epoxy are by cross-linking. The bonding material is also considered to be an adhesive. During continuous contacting of the first layer 12 to the second layer 14, the second layer 14 may be applied onto the first layer 12 and vice versa. The pre-determined rate of motion is typically between 2 to 60 m/min. The system (60) includes a coating mechanism (62) for continuously contacting the first layer 12 of the first impermeable material to the second layer 14 of bonding material at a pre-determined rate of motion. The coating mechanism (62) may be a slot-and-knife coater.

The method (20) also includes B-staging the second layer 14 (24) to induce adhesive properties of the second layer 14. The second layer 14 may be a thermal B/UV B/B-staged film. The B-staging (24) may use radiation such as, for example, UV, x-ray, visible light, infra-red and so forth. The intensity of the UV radiation is between 100 to 10000 mJ/cm², and possibly between 500 to 2000 mJ/cm². The B-staging (24) is carried out for a duration of between 1 second to 300 seconds, and likely for a duration of more than 5 seconds. Alternatively, the B-staging (24) is also able to be carried out using heat, whereby the heat is emitted at a temperature of between 50° C. to 250° C. for a duration of between 1 to 300 seconds. A UV source (66) for carrying out B-staging of the second layer 14 is also included in the system (60). The UV source (66) may be a fusion lamp.

The B-staging of the second layer 14 (24) is able to minimize air pockets between a third layer 16 and the bonding material when the third layer 16 is in contact with the second layer 14. The air pockets result from air bubbles formed in the bonding material. The B-staging of the second layer 14 (24) increases a viscosity of the bonding material which leads to a more uniform surface morphology less likely to be affected by ambient variations resulting in air pockets. In addition, the increase in the viscosity of the bonding material allows film formation in the second layer 14 which also minimizes the air pockets.

In addition, the method (20) also includes pre-heating of the first layer 12 with the B-staged second layer 14 and the third layer 16 of a second impermeable material (26). The second impermeable material is in a form of a continuous copper sheet. The pre-heating (26) activates the B-staged second layer 14 before contacting the third layer 16. Activating the B-staged second layer 14 includes partial melting of the curable epoxy adjacent to an exposed surface of the second layer 14 for increased adhesion to the third layer 16. In addition, pre-heating (26) of the second layer 14 also reduces a quantity of volatiles and dissolved gases in the second layer 14. The pre-heating (26) is carried out at a temperature between 20° C. to 240° C., and possibly between 70° C. to 200° C. The pre-heating (26) is also carried out for a duration of between 1 second to 300 seconds, and possibly between 30 seconds to 200 seconds. The system (60) includes a first heating enclosure (68) for carrying out pre-heating of the first layer 12 with the B-staged second layer 14 and the third layer 16. The first heating enclosure (68) is possibly a pre-cure oven.

The method (20) also includes continuously contacting the third layer 16 of a second impermeable material (28) to the second layer 14 at the pre-determined rate of motion. The pre-determined rate of motion is typically between 2 to 60 m/min. The system (60) also includes at least one coil winding mechanism (64) for continuously contacting the third layer 16 of a second impermeable material to the second layer 14 at the pre-determined rate of motion.

During continuous contacting of the third layer 16 to the activated second layer 14 (28), the second layer 14 may be applied onto the third layer 16 and vice versa. It should be appreciated that the aluminum sheet used for the first layer 12 is thicker than the copper sheet used for the third layer 16. The aluminum sheet is able to provide structural support for the circuit board 10 while the copper sheet is in foil form to aid in conduction properties of the circuit board 10. The aluminum sheet is typically thicker than the copper sheet on the circuit board 10, although there may be exceptions in view of specific design considerations.

In the method (20), there is also application of pressure to the first layer 12 (30) with the B-staged second layer 14 and the third layer 16. The application of pressure (30) is for ensuring bonding of both the first layer 12 and the third layer 16 with the second layer 14 whereby the applied pressure (30) is between 1 to 100 kgf, and possibly between 10 to 50 kgf. A laminator (70) for applying pressure to the first layer 12 with the B-staged second layer 14 and the third layer 16 is also included in the system 60. The laminator (70) is possibly in a form of a series of rollers arranged in a configuration to apply pressure to the layers 12, 14, 16 when the layers 12, 14, 16 pass through the laminator (70).

For the method (20), there is subsequently thermal curing of the B-staged second layer 14 (32). The thermal curing of the B-staged second layer 14 (32) is for curing the epoxy of the bonding material. The thermal curing (32) is carried out at a temperature between 100° C. to 300° C., and possibly above 160° C. Moreover, the thermal curing (32) is carried out for a duration of between 1 minute to 5 minutes, and possibly between 2 minutes to 4 minutes. A second heating enclosure (72) for carrying out thermal curing of the B-staged second layer 14 is also a part of the system (60). The second heating enclosure (72) is possibly a curing oven.

Finally, the method (20) includes singulating each circuit board 10 (34) after thermal curing (32) to prevent both shattering and partial uncuring of the second layer 14. The singulating is possibly carried out before the second layer 14 cools to 100° C. The system (60) also includes a singulating mechanism (74) for singulating each circuit board 10 after thermal curing to prevent both shattering and partial uncuring of the second layer 14. The singulating mechanism (74) can possibly be in a form of a cutter.

It should be appreciated that both the method (20) and the system (60) are able to provide a continuous process which is preferable to a batch process. The continuous process is faster and there is less wastage of materials. B-staging the second layer 14 (24) also minimizes air pockets between the third layer 16 and the bonding material. In addition, the pre-heating (26) of the second layer 14 also reduces a quantity of volatiles and dissolved gases in the second layer 14. As such, the second layer 14 is able to be in a form of a thinner layer compared to if the air pockets, quantity of volatiles and dissolved gases were not minimized. Thus, a lower quantity of the bonding material is used for the second layer 14 and the continuous process correspondingly leads to lower fabrication costs for the circuit board 10. Furthermore, the minimization of the air pockets, quantity of volatiles and dissolved gases also enhances a strength of the circuit board 10.

With reference to primarily FIG. 1, there is provided a circuit board 10. The circuit board 10 may be usable for the fabrication of LEDs, and would have heat dissipation qualities. As shown in FIG. 1, the circuit board 10 is in a form of a multi-layer vertical stacking configuration. The circuit board 10 is possibly fabricated using either the aforementioned method (20) or system (60).

The circuit board 10 includes a first layer 12 of a first impermeable material, the first layer 12 being cut from a continuous sheet. The first impermeable material is aluminum. There is also a second layer 14 of a bonding material on the first layer 12. The bonding material comprises a polymerizable polymer and a curable epoxy, whereby both the polymerization of the polymer and the curing of the epoxy are by cross-linking. The bonding material is also considered to be an adhesive. A third layer of a second impermeable material on the second layer 14 is also included on the circuit board 10. The second impermeable material is copper. It should be appreciated that the aluminum sheet used for the first layer 12 is thicker than the copper sheet used for the third layer 16. The aluminum sheet is able to provide structural support for the circuit board 10 while the copper sheet is in foil form to aid in conduction properties of the circuit board 10.

It is appreciated that the first layer 12 and the third layer 16 are each bonded with the second layer 14, whereby the first layer 12 and the third layer 16 each has an in-plane dimension that is at least ten times greater than a thickness of the second layer 14. It is also possible that the first layer 12 and the third layer 16 each has an in-plane dimension that is either a hundred or a thousand times greater than the thickness of the second layer 14. Thus, it is appreciated that the thickness of the second layer 14 is substantially thinner than the thickness of each of the first layer 12 and the third layer 16.

Furthermore, pre-heating of the second layer 14 of the circuit board 10 reduces a quantity of volatiles and dissolved gases in the second layer 14. Consequently, the at least ten times greater thickness of the first layer 12 and the third layer 16 in relation to the thickness of the second layer 14 increases an elastic modulus of the circuit board 10 to a value greater than 1000.

Thus, it should be appreciated that the circuit board 10 would be stiffer and consequently would be more robust when used for LED applications. Furthermore, fabrication costs are reduced as an amount of the bonding material used for the second layer 14 is minimized.

Whilst the foregoing description has described exemplary embodiments, it will be understood by those skilled in the technology concerned that many variations in details of design, construction and/or operation may be made without departing from the present invention.

1. A method for manufacturing a circuit board, the method including:
continuously contacting a first layer of a first impermeable material to a second layer of bonding material at a pre-determined rate of motion;
B-staging the second layer;
continuously contacting a third layer of a second impermeable material to the second layer at the pre-determined rate of motion; and
thermal curing the B-staged second layer.

2. The method of claim 1, further including:
pre-heating of the first layer with the B-staged second layer and the third layer; and
applying pressure to the first layer with the B-staged second layer and the third layer.

3. The method of claim 1, wherein the bonding material comprises a polymerizable polymer and a curable epoxy, both the polymerization of the polymer and the curing of the epoxy being by cross-linking.

4. The method of claim 1, wherein the first impermeable material is provided from a continuous aluminum sheet and the second impermeable material is provided from a continuous copper sheet.

5-7. (canceled)

8. The method of claim 1, wherein the B-staging is carried out for a duration of between 1 second to 300 seconds.

9. (canceled)

10. The method of claim 1, wherein the B-staging is carried out using radiation selected from a group comprising: UV, x-ray, visible light, and infra-red.

11-14. (canceled)

15. The method of claim 3, wherein the pre-heating activates the B-staged second layer before contacting the third layer.

16-27. (canceled)

28. The method of claim 1, wherein the thermal curing is carried out for a duration of between 1 minute to 5 minutes.

29-33. (canceled)

34. A system for manufacturing a circuit board, the system including:
a coating mechanism for continuously contacting a first layer of a first impermeable material to a second layer of bonding material at a pre-determined rate of motion;
at least one coil winding mechanism for continuously contacting a third layer of a second impermeable material to the second layer;
a UV source for carrying out B-staging the second layer;
a first heating enclosure for carrying out pre-heating of the first layer with the B-staged second layer and the third layer;
a laminator for applying pressure to the first layer with the B-staged second layer and the third layer; and
a second heating enclosure for carrying out thermal curing of the B-staged second layer.

35. (canceled)

36. The system of claim 34, wherein the bonding material comprises a cross-linkable polymer and a curable epoxy.

37. The system of claim 34, wherein the first impermeable material is a continuous aluminum sheet and the second impermeable material is a continuous copper sheet.

38-50. (canceled)

51. The system of claim 34, further including a singulating mechanism for singulating each circuit board after thermal curing to prevent both shattering and partial uncuring of the second layer.

52. (canceled)

53. A circuit board, the circuit board including:
a first layer of a first impermeable material, the first layer being cut from a continuous sheet;
a second layer of a bonding material on the first layer; and
a third layer of a second impermeable material on the second layer; wherein the first layer and the third layer are each bonded with the second layer, the first layer and the third layer each having an in-plane dimension that is at least ten times greater than a thickness of the second layer.

54. The circuit board of claim 53, wherein the in-plane dimension of the first layer and the third layer each has is either a hundred or a thousand times greater than the thickness of the second layer.

55. The circuit board of claim 53, wherein the first impermeable material is aluminum and the second impermeable material is copper.

56. (canceled)

57. The circuit board of claim 54, wherein the at least ten times greater thickness of the first layer and the third layer in relation to the thickness of the second layer increases an elastic modulus of the circuit board to a value greater than 1000.
